(19) United States
(12) Patent Application Publication
(10) Pub. No.: US 2010/0209730 A1
(43) Pub. Date: Aug. 19, 2010

(54) Coated article with sputter-deposited transparent conductive coating for refrigeration/freezer units, and method of making the same

(75) Inventors: Scott V. Thomsen, South Lyon, MI (US); Jingyu Lao, Saline, MI (US); Kevin O'Connor, Windsor (CA)

Correspondence Address: NIXON & VANDERHYE, PC, 901 NORTH GLEBE ROAD, 11TH FLOOR, ARLINGTON, VA, 22203, US

(73) Assignee: Guardian Industries Corp.,, Auburn Hills, MI (US)

(21) Appl. No.: 12/458,790

(22) Filed: Jul. 22, 2009

Related U.S. Application Data
(63) Continuation-in-part of application No. 12/379,382, filed on Feb. 19, 2009.

(51) Int. Cl. B32B 17/06; C23C 14/34

(52) U.S. Cl. 428/623; 204/192.29

(57) ABSTRACT

Certain example embodiments relate to sputter-deposited transparent conductive coatings (TCCs) for use in, for example, refrigeration and/or freezer units (e.g., as doors, windows, etc.). The TCC may include a silver-based conductive layer, at least partially protected by a zirconium oxide overcoat. Such TCCs may be provided in connection with monolithic or multi-substrate arrangements in different example embodiments. Certain example embodiments may involve “active” modes, where a silver-based layer in the TCC may receive a voltage, e.g., to reduce the likelihood of frosting, freezing, fogging, condensation, and/or the like, on the glass substrate that supports the TCC.

### CROSS-REFERENCE TO RELATED APPLICATION

This application is a continuation-in-part (CIP) of U.S. application Ser. No. 12/379,382, filed Feb. 19, 2009, the entire content of which is hereby incorporated herein by reference.

### FIELD OF THE INVENTION

Certain example embodiments of this invention relate to coated articles that include sputter-deposited coatings, and/or methods of making the same. More particularly, certain example embodiments of this invention relate to sputter-deposited transparent conductive coatings (TCCs) for use in, for example, refrigeration and/or freezer units (e.g., as doors, windows, etc.). Certain example embodiments may involve “active” modes, where a silver-based layer in the TCC may receive a voltage, e.g., to reduce the likelihood of frosting, freezing, fogging, condensation, and/or the like, on the glass substrate that supports the TCC.

### BACKGROUND AND SUMMARY OF EXAMPLE EMBODIMENTS OF THE INVENTION

The use of transparent conductive coatings (TCCs) in refrigeration and freezer units is known. See, for example, U.S. Pat. Nos. 7,246,470; 6,268,594; 6,144,017; and 5,852,284, and U.S. Publication No. 2006/0059861, each of which is hereby incorporated herein by reference in its entirety. In general, one or more glass substrates inside the unit helps absorb heat from outside the unit and also helps reduce transmission of cooler to the exterior of the unit. In this regard, TCCs in refrigeration and freezer units help such units to act as a heat barrier or heat sink.

While efficacious for many known layer systems, the use of sputter-coating has been known to result in mechanical durability qualities less than that achieved by known pyrolytic techniques. As a reverse function, however, sputter-coated systems often achieve better infrared reflectance than typical pyrolytic coatings. Also, sputter-coated glasses have generally been recognized as having superior optical and thermal performance characteristics than pyrolytically formed coatings, such as having improved coating uniformity, good emittance, and better solar performance characteristics.

Unfortunately, “hard coatings” are needed for refrigeration and freezer units, since pyrolytic layer systems are durable enough to withstand the harsh environments and repeated use in a commercial setting such as a grocery store. However, it will be appreciated that if a sputter-coating technique could be devised for a particular coating system wherein the mechanical durability qualities of the sputter-coated system could approach or equal that of a pyrolytic technique, while at the same time achieving the enhanced benefits of sputter-coated technology, a significant step forward in the art would be made.

Thus, it will be appreciated that there is a need in the art for sputter-deposited transparent conductive coating (TCC) layer systems that are suitable for use in refrigeration and freezer units, e.g., as doors, windows, and/or the like, and methods of making the same.

In certain example embodiments of this invention, a method of making an article for a refrigeration or freezer unit is provided. First and second substantially parallel and spaced apart glass substrates are provided, with the first substrate being provided for an interior side of the article and the second substrate being provided for an exterior side of the article. One or more transparent conductive coatings (TCCs) are sputter-deposited, respectively, on one or more major surfaces of the first and/or second substrates. At least the first and second substrates are thermally tempered. Each said TCC is silver-based and includes a zirconium oxide protective overcoat.

In certain example embodiments of this invention, a method of making an article for a refrigeration or freezer unit is provided. A glass substrate is provided. One or more transparent conductive coatings (TCCs) are sputter-deposited on one or more respective major surfaces of the substrate. At least the substrate is thermally tempered. Each said TCC comprises: a first barrier layer of silicon nitride provided on the second substrate, a first nickel chromium inclusive contact layer provided on the first barrier layer, a silver-inclusive conductive layer provided on the first contact layer, a second nickel chromium inclusive contact layer provided on the conductive layer, and a second barrier layer of silicon nitride provided on the second contact layer, and a protective overcoat comprising zirconium oxide provided on the second contact layer. Each said TCC has a sheet resistance between about 3-15 ohms/square.

In certain example embodiments of this invention, an assembly for a refrigeration or freezer unit is provided. First and second substantially parallel and spaced apart glass substrates are provided. At least one sputter-deposited transparent conductive coating (TCC) is provided, with each said TCC being supported by one major surface of the first or second substrate. Each said TCC comprises: a first barrier layer of silicon nitride provided on the second substrate, a first nickel chromium inclusive contact layer provided on the first barrier layer, a silver-inclusive conductive layer provided on the first contact layer, a second nickel chromium inclusive contact layer provided on the conductive layer, a second barrier layer of silicon nitride provided on the second contact layer, and a zirconium oxide protective overcoat provided on the second contact layer. Each said TCC has a sheet resistance of about 3-15 ohms/square.

In certain example embodiments of this invention, an assembly for a refrigeration or freezer unit is provided. A glass substrate is provided. At least one sputter-deposited transparent conductive coating (TCC) is provided, with each said TCC being supported by one major surface of the substrate. Each said TCC comprises: a first barrier layer of silicon nitride provided on the second substrate, a first nickel chromium inclusive contact layer provided on the first barrier layer, a silver-inclusive conductive layer provided on the first contact layer, a second nickel chromium inclusive contact layer provided on the conductive layer, a second barrier layer of silicon nitride provided on the second contact layer, and a zirconium oxide protective overcoat provided on the second contact layer. Each said TCC has a sheet resistance of about 3-15 ohms/square.

In certain example embodiments of this invention, a method of making a coated article is provided. A glass substrate having at least one major surface to be coated is provided. A transparent conductive coating (TCC) is sputtered on the glass substrate. The TCC comprises, in order from nearest to farthest from the glass substrate: a first barrier layer of silicon nitride, a first nickel chromium inclusive contact layer provided on the first barrier layer, a silver-inclusive conductive layer provided on the first contact layer, a second nickel chromium inclusive contact layer provided on the conductive layer, a second barrier layer of silicon nitride provided on the second contact layer, and a zirconium oxide protective overcoat provided on the second contact layer. Each said contact layer is about 5-20 angstroms thick. The silver-inclusive conductive layer is about 3-20 nm thick, causing the TCC to have a sheet resistance of about 3-15 ohms/square. In certain example embodiments of this invention, a method of making a horizontally oriented refrigerator/freezer unit is provided. A coated article according to this method is provided, and the coated article is built into the horizontally oriented refrigerator/freezer unit as a door or window.

Such example assemblies may be used in connection with refrigeration or freezer doors, windows, sliders, drawers, and/or the like. In this regard, such example assemblies may be built into refrigeration or freezer units, regardless of whether those units are generally upright or horizontal units.

Certain example embodiments involve either “passive” or “active” TCCs. In this regard, active TCCs may receive a voltage from a power source, e.g., via a bus bar and contact configuration according to certain example embodiments.

The sputter-deposited transparent conductive coatings of certain example embodiments may comprise: a first barrier layer of silicon nitride provided on the substrate, a first nickel chromium inclusive contact layer provided on the first barrier layer, a silver-inclusive conductive layer provided on the first contact layer, a second nickel chromium inclusive contact layer provided on the conductive layer, a second barrier layer of silicon nitride provided on the second contact layer, and a protective overcoat comprising zirconium oxide provided on the second barrier layer.

The example embodiments described herein may be used to build an assembly or intermediate product, which may be built into a refrigeration or freezer unit, e.g., as a glass window, door, or other like transparent member.

In certain example embodiments of this invention, a method of making a coated article comprising a coating supported by a substrate is provided. A transparent conductive coating is sputter-deposited on a first major surface of the substrate, with the transparent conductive coating comprising: a first barrier layer of silicon nitride provided on the substrate, a first nickel chromium inclusive contact layer provided on the first barrier layer, a silver-inclusive conductive layer provided on the first contact layer, a second nickel chromium inclusive contact layer provided on the conductive layer, a second barrier layer of silicon nitride provided on the second contact layer, and a protective overcoat comprising zirconium oxide provided on the second barrier layer. The same or similar transparent conductive coating may be sputter-deposited on a second major surface of the substrate. One or more of these coated articles may be built into an assembly or intermediate product, which may be built into a refrigerator or freezer door, window, etc., which may, in turn, be built into a refrigerator or freezer.

The features, aspects, advantages, and example embodiments described herein may be combined to realize yet further embodiments.

### BRIEF DESCRIPTION OF THE DRAWINGS

These and other features and advantages will be better and more completely understood by reference to the following detailed description of exemplary illustrative embodiments in conjunction with the drawings, of which:

FIG. 1 is a coated article supporting a sputter-deposited transparent conductive coating, in accordance with an example embodiment;

FIG. 2a is an illustrative “passive” two substrate configuration including sputter-deposited transparent conductive coatings, in accordance with an example embodiment;

FIG. 2b is an illustrative “active” two substrate configuration including sputter-deposited transparent conductive coatings, in accordance with an example embodiment;

FIG. 3 is an illustrative three substrate configuration including sputter-deposited transparent conductive coatings, in accordance with an example embodiment;

FIG. 4 is a first illustrative refrigeration or freezer unit, in accordance with an example embodiment; and

FIG. 5 is a second illustrative refrigeration or freezer unit, in accordance with an example embodiment.

### DETAILED DESCRIPTION OF EXAMPLE EMBODIMENTS OF THE INVENTION

Certain example embodiments of this invention relate to transparent conductive coatings (TCC) that may be used in refrigerator or freezer unit applications, and methods of making the same. Certain example embodiments surprisingly and unexpectedly enable sputter-deposited coatings to survive harsh environments. For example, zirconium oxide (ZrOx) may be used as a protective overcoat to protect an underlying Ag layer, e.g., from corrosion in the atmosphere. In other words, the techniques of certain example embodiments help provide a more durable sputter-deposited coating.

The coatings described herein may be used in connection with a variety of different configurations. For example, the coatings described herein may be used in connection with monolithic windows/doors, two- or three-pane insulating glass (IG) embodiments, etc. In certain example embodiments, the glass substrates with or without the coating sputter-deposited thereon may be thermally tempered.

Certain example coated articles may be combined in a window pack with other clear or low-E coated lites or used monolithically, e.g., to manage the thermal characteristics of a window pack to keep the inside surface temperature below a threshold temperature and reflect away heat from the outside. Of course, it will be appreciated that the performance demands on the design may vary, for example, based on the actual characteristics of the refrigeration or freezer unit design. Window packs containing uncoated lites, single-sided coated lites and/or double-sided coated lites may be combined to achieve the most cost effective solution for targeted performance characteristics. The coated lites described herein may be used in combination with, or as a substitute to, pyrolytic coatings. The details of certain example configurations are provided below, although it will be appreciated that the same, similar, and/or other configurations also may be present in certain example embodiments.

Furthermore, certain example embodiments may be either “active” or “passive” configurations. That is, certain example embodiments may be “active” in the sense that they provide a voltage to the TCC (e.g., through one or more bus bars connected to a power source). By providing a low voltage to the TCC in accordance with certain example embodiments, the likelihood of frosting, freezing, fogging, condensation, and/or the like, advantageously may be reduced.

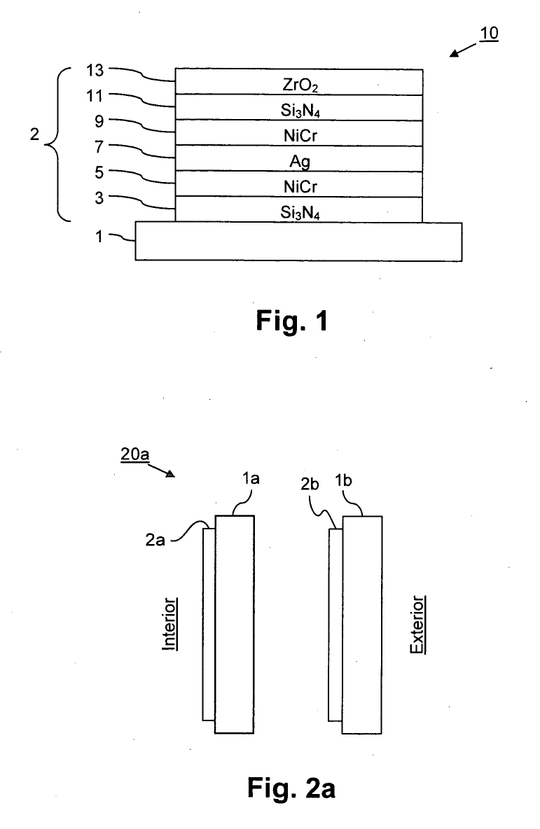

Referring now more particularly to the drawings in which like reference numerals indicate like components throughout the several views, FIG. 1 is an example coated article 10 including a sputter-deposited TCC, in accordance with an example embodiment of this invention. More particularly, FIG. 1 is a coated article 10 that includes a glass substrate 1 supporting a first sputter-deposited transparent conductive coating 2 suitable for use in refrigerator and freezer unit applications, in accordance with an example embodiment. As explained in greater detail below, zirconium oxide (e.g., ZrO₂ or other suitable stoichiometry) may be provided (e.g., sputter-deposited) as a protective overcoat so that a conductive layer (typically Ag) is protected from harsh environmental conditions, with the conductive layer being sandwiched between first and second contact layers and first and second barrier layers, such that the contact layers are provided between the conductive layer and the barrier layers, and such that the zirconium oxide layer is the outermost layer among at least these layers.

FIG. 1 includes a sputter-deposited TCC layer stack 2 supported by a substrate 1. In the layer stack 2 of FIG. 1, a first barrier layer 3, which may include silicon nitride (e.g., Si₃N₄ or other suitable stoichiometry), for example, is provided on the substrate 1. A first contact layer 5, which may be a nickel-chromium inclusive layer (e.g., NiCr or oxidized as NiCrOx), for example, is provided on the first barrier layer 3. A conductive layer 7 is provided on the first contact layer 5, with the conductive layer 7 including Ag or any other suitable conductive material. A second contact layer 9 which, as above, may be a nickel-chromium inclusive layer (e.g., NiCr or oxidized NiCrOx), for example, is provided on the conductive layer 7. A second barrier layer 11 which, as above, may include silicon nitride (e.g., Si₃N₄ or other suitable stoichiometry), for example, is provided on the second contact layer 9. A protective overcoat 13 of zirconium oxide (e.g., ZrO₂ or other suitable stoichiometry) is applied over the second barrier layer 11, so as to protect the conductive layer 7 from the harsh environment. At least the first barrier layer 3 may be provided to a thickness sufficient to reduce the likelihood of migration of sodium from the glass substrate 1 into the conductive layer 7, and at least the second barrier layer 11 may be provided to a thickness sufficient to reduce the likelihood of migration of zirconium from the protective layer 13 into the conductive layer 7. One or both of the contact layers may be metal layers in certain example embodiments of this invention. Additionally or alternatively, one or both of the barrier layers may be doped with a suitable dopant such as, for example, aluminum.

As will be appreciated, the thickness of the conductive layer 7 in FIG. 1 may be varied so as to affect the sheet resistance of the layer stack 2. For example, a thickness of about 6.1 nm will result in a sheet resistance of about 15 ohms/square, whereas a thickness of about 12 nm will result in a sheet resistance of about 5 ohms/square. Indeed, the inventors of the instant application have determined that the amount of Ag can be increased in certain example embodiments so as to reduce the sheet resistance to about 4 ohms/square or 5 ohms/square without significantly jeopardizing the Ag (e.g., as a result of coming into contact with the harsh environment).

In certain example embodiments, the same and/or different TCC layer stack 2 may be provided on the opposite side of the substrate 1, as by sputtering or any other suitable technique. Regardless of whether a TCC is provided on one or both sides of the substrate 1, the monolithic coated article 10 may be build into a refrigeration or freezer unit, e.g., as a part of a door, slider, window, drawer, or other like component.

Example physical thicknesses (in nm) of the layers in the sputter-deposited TCC 2 are provided in the table below:

| | | | | More |
|---|---|---|---|---|
| | Example | Example | Preferred | Preferred |
| Layer | 1 (nm) | 2 (nm) | Range (nm) | Range (nm) |
| ZrO₂ | 5-10 | 5-10 | 1.5-50 | 5-20 |
| Top Si₃N₄ | 33.7 | 33.7 | 10-100 | 25-60 |
| Top NiCr | 0.8 | 1.4 | 0.5-10 | 0.7-5 |
| Ag | 6.1 | 12 | 2-25 | 3-20 |
| Bottom NiCr | 1.1 | 2.0 | 0.5-10 | 0.7-5 |
| Bottom Si₃N₄ | 38.2 | 38.2 | 10-150 | 20-80 |

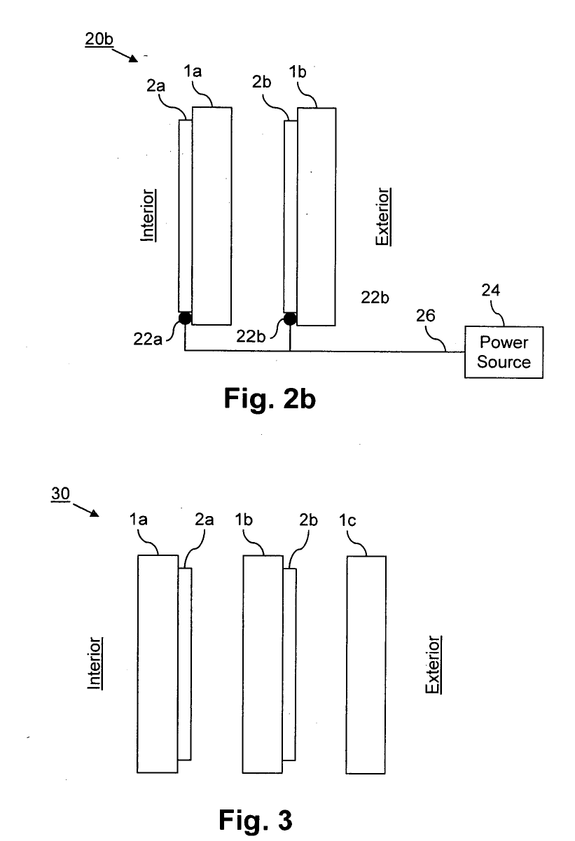

FIG. 2a is an illustrative “passive” two substrate configuration 20a including sputter-deposited transparent conductive coatings, in accordance with an example embodiment. FIG. 2a differs from the FIG. 1 example embodiment in several ways. For example, the FIG. 1 example embodiment represents a monolithic design, whereas the FIG. 2a example embodiment represents a design more similar to an insulating glass (IG) unit. That is, in the FIG. 2a example embodiment, first and second substantially parallel and spaced apart glass substrates 1a and 1b are provided. First and second TCCs 2a and 2b are respectively sputter-deposited on the first and second glass substrates. The first and second TCCs 2a and 2b may be the same or different TCCs in certain example embodiments. That is, in certain example embodiments, they may have the same or different sheet resistances (e.g., depending on, for example, the amount of conductive material in conductive layer 7). In certain example embodiments, they may be differently deposited (e.g., one by sputtering, one by a pyrolytic technique, etc.).

The FIG. 2a example embodiment is “passive” in the sense that no electrical current is provided to the first and second conductive layers 2a and 2b. As explained in greater detail below, the FIG. 2b example embodiment differs from the FIG. 2a example embodiment in this regard.

Although FIG. 2a shows the first and second TCCs 2a and 2b being respectively provided on the major surfaces of the first and second substrates 1a and 1b being closest to the interior of the assembly, other configurations are possible in connection with different example embodiments. For example, TCCs may be applied to any one or more of the four major surfaces of the assembly such as, for example, the major surfaces of the first and second substrates 1a and 1b being closest to the exterior of the assembly, major surfaces of the first and second substrates 1a and 1b that face one another, etc.

Although not shown in FIG. 2a, one or more edge seals may be provided between the first and second substrates 1a and 1b, e.g., around the periphery of the substrates in certain example embodiments. These edge seals may be rubber, foam, metal, or other spacers, or more robust metal, glass frit, or other edge seals, in different example embodiments of this invention. Additionally, the cavity formed between the two substrates may be at least partially evacuated (e.g., to a pressure less than atmospheric) and/or may be filled with a gas such as, for example, argon, krypton, xenon, or any other inert noble or appropriate gas.

FIG. 2b is an illustrative “active” two substrate configuration 20b including sputter-deposited transparent conductive coatings, in accordance with an example embodiment. As noted above, the FIG. 2b example embodiment is similar to the FIG. 2a example embodiment, except that the FIG. 2b example embodiment is “active.” In this regard, first and second contacts 22a and 22b are electrically connected to the first and second TCCs 2a and 2b, respectively. These contacts 22a and 22b provide a voltage from the power source 24 to the respective first and second TCCs 2a and 2b, via one or more bus bars 26. Such bus bars may be Ag-based bus bars in certain example embodiments, and may be concealed behind the frame of the larger unit in certain example embodiments.

As above, more or fewer TCCs may be provided on the first and second substrates 1a and 1b, on the same or different major surfaces of the glass substrates 1a and 1b. Any additional TCCs may or may not be electrically connected to the power source 24, e.g., via respective contacts and bus bar connections. For example, if frost is most likely to form on the innermost surface of the innermost substrate, only the TCC(s) formed thereon may be electrically connected to the power source 24 in certain example embodiments.

FIG. 3 is an illustrative three substrate configuration 30 including sputter-deposited transparent conductive coatings, in accordance with an example embodiment. As alluded to above, one or more substrates may be provided in connection with certain example embodiments, and any one or more of such substrates may have a TCC sputter-deposited, directly or indirectly, on one or both major surfaces thereof—provided that one said substrate includes the sputter-deposited TCC. Furthermore, certain example embodiments may include a decorative outer glass substrate that may be the same as or different from the other glass substrates provided in the assembly.

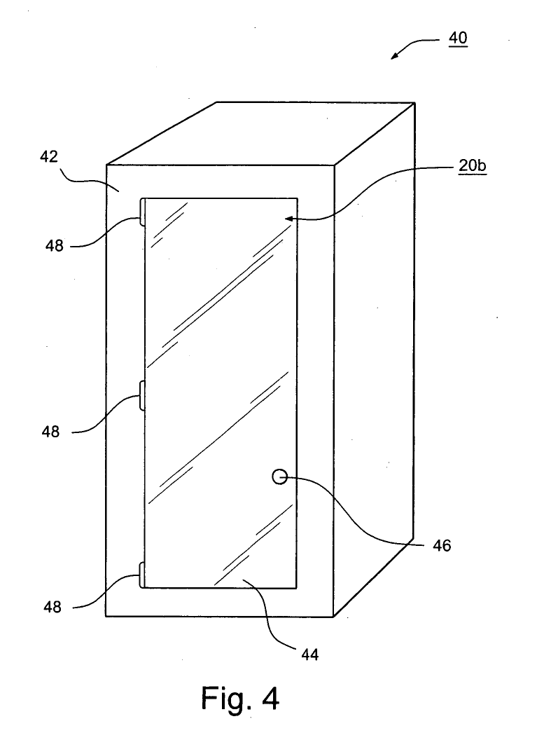

FIG. 4 is a first illustrative refrigeration or freezer unit 40, in accordance with an example embodiment. The first illustrative refrigeration or freezer unit 40 of FIG. 4 includes a main body portion 42 and a glass door 44. The glass door 44 has a handle or knob 46 attached thereto to facilitate the opening and closing of the door 44. In the FIG. 4 example embodiment, the door 4 opens outwardly via one or more hinges 48. Of course, in different example embodiments, the door 4 may be a sliding door.

The glass assembly 20b used in connection with the FIG. 4 embodiment is an insulating glass arrangement similar to that shown in FIG. 2b. Of course, any other arrangement could be implemented in connection with different example embodiments of this invention. The power source responsible for cooling the overall unit 40 may also be used to provide power to the “active” TCC coatings formed on the glass substrates used in the door 44. It will be appreciated that this may help reduce the likelihood of frosting, freezing, fogging, condensation, and/or the like, in or on the door 44. It also will be appreciated that one or more portions of the main body 42 of the unit 40 may be replaced with glass windows or the like. Such glass windows may be of the same general design as arrangement 20b used for the door 44, although different example arrangements may be used independent of the particular arrangement selected for the door 44.

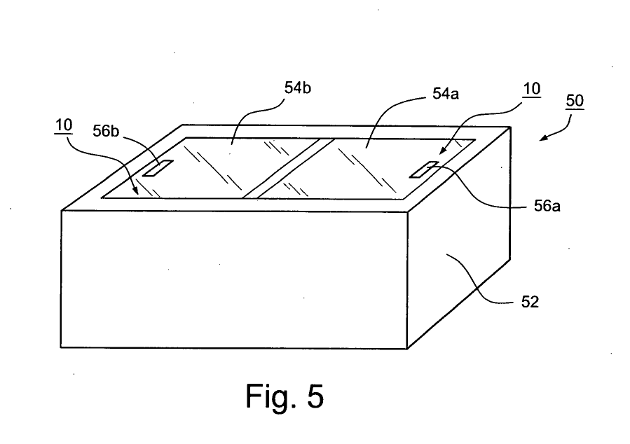

FIG. 5 is a second illustrative refrigeration or freezer unit 50, in accordance with an example embodiment. The unit 50 includes a main body portion 52 and two sliding doors 54a and 54b. Each sliding door 54a and 54b includes a handle 56a and 56b. Of course, in certain example embodiments, the doors may be hinged so that they open outwardly, for instance. In certain example embodiments, only one sliding door 54 may be provided. In any event, the sliding doors 54a and 54b include arrangement 10 as shown in the FIG. 1 example embodiment. Thus, the sliding doors 54a and 54b are monolithic. Of course, other arrangements are possible. For example, the sliding doors 54a and 54b may instead include two-, three-, or more glass substrate arrangements. Although the FIG. 1 example embodiment is not “active,” it may be made active, e.g., by providing a suitable electrical connection to a power source (for instance, via a suitable connection and bus bar arrangement). Similar to as above, it will be appreciated that one or more portions of the main body 52 of the unit 50 may be replaced with glass windows or the like. Such glass windows may be of the same general design as arrangement 10b used for the doors 54a and 54b, although different example arrangements may be used independent of the particular arrangement selected for the doors 54a and 54b. Additionally, different designs may be used for the different doors 54a and 54b, and/or one of these doors may be replaced with a window of the same or different design in different example embodiments.

The following table shows example properties for certain illustrative monolithic products in accordance with certain example embodiments.

| | 5 ohm/square Example | 15 ohm/square Example |
|---|---|---|
| Emisivity | 0.06 | 0.14-0.16 |
| Color Uniformity | Good | Good |
| Light Transmission | 65% | 82% |

When assembled, the entire door may have a light transmission of at least about 50%, more preferably at least about 60%.

In certain example embodiments, the lites may have a common thickness (e.g., a thickness of 3.2 mm, 4 mm, or some other thickness), although the lites need have the same thickness in all embodiments. The glass substrates of certain example embodiments may be thermally tempered, e.g., at a temperature of at least about 580 degrees C., more preferably at least about 600 degrees C., with or without the sputter-deposited TCC formed thereon. As alluded to above, conventional sputter-deposited coatings cannot withstand this level of heat. Thus, the ability to thermally temper and to include such sputter-deposited coatings in a product to be used in connection with a refrigeration or freezer unit is an advantage that is superior to conventional techniques that prohibit the use of sputter-deposited coatings in such applications.

Advantageously, the sputter-deposited TCC coatings of certain example embodiments may lead to better color uniformity and/or emissivity characteristics, at least as compared to current products that involve pyrolytic coatings only. Thus, the example embodiments described herein may be used in new applications and/or areas where a higher performance and/or aesthetic appeal is/are necessary or desirable. Furthermore, the lower emissivity characteristics of certain example embodiments also may be used to improve window pack performance and ultimately reduce OEM costs, e.g., by reducing the number of lites required for the design, improving efficiency by reducing cooling costs for the overall units (e.g., by keeping heat out and/or coolness air), etc.

As noted above, it will be appreciated that certain example embodiments may include one, two, or three and substrate arrangements. At least one substrate in each such arrangement may include a sputtered TCC coating provided on at least one surface thereof. Thus, in certain example embodiments, non-decorative substrates may have sputtered TCC coating coatings disposed on zero, one, or two major surfaces thereof. Furthermore, when sputter-deposited TCCs are included in different example embodiments, it will be appreciated that such coatings may be in the range of 3-20 ohms/square (e.g., 4, 5, or 15 ohms/square) sputter-deposited TCCs, e.g., as described in detail above. The different sputter-deposited TCC coatings may be used in any suitable combination or sub-combination in different example embodiments of this invention.

Three samples are presented in the following table:

| | | |
|---|---|---|
| Sample 1 | Sample 2 | Sample 3 |

| | | | | | | |
|---|---|---|---|---|---|---|
| ZrOx | 70 | Å | 70 | Å | 70 | Å |
| Top Si₃N₄ | 337 | Å | 337 | Å | 337 | Å |
| Top NiCr | 8 | Å | 12 | Å | 14 | Å |
| Ag | 58 | Å | 58 | Å | 130 | Å |
| Bottom NiCr | 11 | Å | 15 | Å | 21 | Å |
| Bottom Si₃N₄ | 382 | Å | 382 | Å | 371 | Å |

In these three samples (and in certain example embodiments), the zirconium oxide overcoat thickness is centered around 7 nm. Also, in these three samples (and in certain example embodiments), the thickness of the Ag in the 4 ohm/square coating is centered around 13 nm. Of course, other thicknesses for the zirconium overcoat and the silver may be used in accordance with different samples and/or example embodiments. The table that follows provides optical and other properties of these three further samples:

| | | Sample 1 | Sample 2 | Sample 3 |
|---|---|---|---|---|
| Monolithic, | TY | 76.5 | 72.7 | 62.0 |
| As Coated | ε | 0.16 | 0.16 | 0.06 |
| (4 mm clear) | Rs | 13.0 | 13.0 | 4.5 |
| Monolithic, | TY | 81.7 | 77.7 | 65.5 |
| Heat Treated | ε | 0.14 | 0.14 | 0.05 |
| (4 mm clear) | Rs | 10.5 | 10.5 | 4.0 |
| Thermal | Visible | 82.3 | | 65.0 |
| Perf. - HT | Transmission | | | |
| Monolithic | Hemi. | 0.14 | 0.14 | 0.05 |
| (4 mm) | Emmisivity | | | |

Although certain example embodiments have been described in connection with low and/or high conductivity TCC layers, multiple TCC layers may have the same conductivity and/or sheet resistance. Moreover, the TCC layers may have sheet resistances of anywhere between about 3-20 ohms/square. High conductivity layers may have sheet resistances at the lower end of this range (e.g., from about 3-8 ohms/square as described above), whereas low conductivity layers may have sheet resistances at the upper end of the range (e.g., from about 12-15 ohms/square as described above). Of course, the low and high conductivity TCC layers are not limited to these exact ranges. Moreover, TCC layers according to example embodiments may fall within the example ranges above, regardless of whether separate “high” and “low” conductivity layers or multiple layers with the same or similar conductivities are implemented.

In certain example embodiments, the door or window packs may or may not be sealed. In such embodiments, the coatings may be designed so as to have a suitably high durability to survive any harsh environments they encounter. The inclusion of a zirconium oxide overcoat may help ensure such durability in certain example embodiments.

Although certain example embodiments have been described as relating to refrigerator or freezer applications, it will be appreciated that the example techniques described herein may be applied to other applications. For example, the example techniques described herein may be applied to other applications where it is desirable to have a durable sputter-deposited coating capable of surviving potentially harsh conditions. Furthermore, the techniques of certain example embodiments may be applied to other electronics and/or appliance applications.

While a particular layer or coating may be said to be “on” or “supported by” a surface or another coating (directly or indirectly), other layer(s) and/or coatings may be provided therebetween. Thus, for example, a coating may be considered “on” and “supported by” a surface even if other layer(s) are provided between layer(s) and the substrate. Moreover, certain layers or coatings may be removed in certain embodiments, while others may be added in other embodiments of this invention without departing from the overall spirit of certain embodiments of this invention. Thus, by way of example, an encapsulating coating applied in liquid sol-gel form in accordance with an example embodiment may be said to be “on” or “supported by” a sputtering target material, even though other coatings and/or layers may be provided between the sol-gel formed coating and the target material.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

What is claimed is:

1. A method of making an article for a refrigeration or freezer unit, the method comprising:
providing first and second substantially parallel and spaced apart glass substrates, the first substrate being provided for an interior side of the article and the second substrate being provided for an exterior side of the article;
sputter-depositing one or more transparent conductive coatings (TCCs), respectively, on one or more major surfaces of the first and/or second substrates; and
thermally tempering at least the first and second substrates,
wherein each said TCC is silver-based and includes a zirconium oxide protective overcoat.

2. The method of claim 1, wherein:
each said TCC comprises:
a first barrier layer of silicon nitride provided on the second substrate,
a first nickel chromium inclusive contact layer provided on the first barrier layer,
a silver-inclusive conductive layer provided on the first contact layer,
a second nickel chromium inclusive contact layer provided on the conductive layer, and
a second barrier layer of silicon nitride provided on the second contact layer, and
the protective overcoat is provided on the second contact layer.

3. The method of claim 2, wherein each said TCC has a sheet resistance of about 4 ohms/square.

4. The method of claim 2, wherein each said TCC has a sheet resistance of about 5 ohms/square.

5. The method of claim 2, wherein each said TCC has a sheet resistance of 3-15 ohms/square.

6. The method of claim 2, wherein the first and/or second barrier layer(s) is/are doped with aluminum.

7. The method of claim 2, wherein each said contact layer is about 5-20 angstroms thick.

8. The method of claim 7, wherein the silver-inclusive conductive layer is about 3-20 nm thick.

9. The method of claim 1, further comprising electrically connecting each said TCC to a power source via at least one bus bar.

10. The method of claim 9, wherein the power source, in operation, is configured to provide a voltage to the TCC to reduce the likelihood of frosting, freezing, fogging, and/or condensation in or on the article.

11. The method of claim 1, wherein the article is a door for the refrigeration or freezer unit.

12. The method of claim 1, further comprising providing at least two TCCs on major surfaces of the first and/or second substrates.

13. A method of making a refrigeration or freezer unit, the method comprising:
making an article according to the method of claim 1; and
building the article into the unit.

14. A method of making an article for a refrigeration or freezer unit, the method comprising:
providing a glass substrate;
sputter-depositing one or more transparent conductive coatings (TCCs) on one or more respective major surfaces of the substrate;
thermally tempering at least the substrate,
wherein each said TCC comprises:
a first barrier layer of silicon nitride provided on the second substrate,
a first nickel chromium inclusive contact layer provided on the first barrier layer,
a silver-inclusive conductive layer provided on the first contact layer,
a second nickel chromium inclusive contact layer provided on the conductive layer, and
a second barrier layer of silicon nitride provided on the second contact layer, and
a protective overcoat comprising zirconium oxide provided on the second contact layer, and
wherein each said TCC has a sheet resistance between about 3-15 ohms/square.

15. The method of claim 14, wherein the first and/or second barrier layer(s) is/are doped with aluminum.

16. The method of claim 14, wherein each said contact layer is about 5-20 angstroms thick, and wherein the silver-inclusive conductive layer is about 3-20 nm thick.

17. The method of claim 14, further comprising electrically connecting each said TCC to a power source via at least one bus bar.

18. An assembly for a refrigeration or freezer unit, comprising:
first and second substantially parallel and spaced apart glass substrates;
at least one sputter-deposited transparent conductive coating (TCC), each said TCC being supported by one major surface of the first or second substrate;
wherein each said TCC comprises:
a first barrier layer of silicon nitride provided on the second substrate,
a first nickel chromium inclusive contact layer provided on the first barrier layer,
a silver-inclusive conductive layer provided on the first contact layer,
a second nickel chromium inclusive contact layer provided on the conductive layer,
a second barrier layer of silicon nitride provided on the second contact layer, and
a zirconium oxide protective overcoat provided on the second contact layer, and
wherein each said TCC has a sheet resistance of about 3-15 ohms/square.

19. The assembly of claim 18, wherein the first and/or second barrier layer(s) is/are doped with aluminum.

20. The assembly of claim 18, wherein the first and second substrates have a visible transmission of at least 50%.

21. The assembly of claim 18, wherein each said contact layer is about 5-20 angstroms thick, and
wherein the silver-inclusive conductive layer is about 3-20 nm thick.

22. The assembly of claim 18, further comprising one or more contacts in electrical connection with (1) each said TCC, respectively, and (2) at least one bus bar.

23. The assembly of claim 22, further comprising a seal between the first and second substrates around edges thereof.

24. The assembly of claim 23, wherein a cavity between the first and second substrates is filled with an inert gas.

25. A refrigeration or freezer unit, comprising the assembly of claim 18.

26. An assembly for a refrigeration or freezer unit, comprising:
a glass substrate;
at least one sputter-deposited transparent conductive coating (TCC), each said TCC being supported by one major surface of the substrate;
wherein each said TCC comprises:
a first barrier layer of silicon nitride provided on the second substrate,
a first nickel chromium inclusive contact layer provided on the first barrier layer,
a silver-inclusive conductive layer provided on the first contact layer,
a second nickel chromium inclusive contact layer provided on the conductive layer,
a second barrier layer of silicon nitride provided on the second contact layer, and
a zirconium oxide protective overcoat provided on the second contact layer, and
wherein each said TCC has a sheet resistance of about 3-15 ohms/square.

27. The assembly of claim 26, wherein the first and/or second barrier layer(s) is/are doped with aluminum.

28. The assembly of claim 27, wherein each said contact layer is about 5-20 angstroms thick, and wherein the silver-inclusive conductive layer is about 3-20 nm thick.

29. The assembly of claim 26, further comprising one or more contacts in electrical connection with (1) each said TCC, respectively, and (2) at least one bus bar.

30. A refrigeration or freezer unit, comprising the assembly of claim 26.

31. A method of making a coated article, the method comprising:
providing a glass substrate having at least one major surface to be coated; and
sputtering, on the glass substrate, a transparent conductive coating (TCC) comprising, in order from nearest to farthest from the glass substrate:
a first barrier layer of silicon nitride,
a first nickel chromium inclusive contact layer provided on the first barrier layer,
a silver-inclusive conductive layer provided on the first contact layer,
a second nickel chromium inclusive contact layer provided on the conductive layer,
a second barrier layer of silicon nitride provided on the second contact layer, and
a zirconium oxide protective overcoat provided on the second contact layer,
wherein each said contact layer is about 5-20 angstroms thick, and
wherein the silver-inclusive conductive layer is about 3-20 nm thick, causing the TCC to have a sheet resistance of about 3-15 ohms/square.

32. A method of making a horizontally oriented refrigerator/freezer unit, the method comprising:
providing a coated article according to the method of claim 31; and
building the coated article into the horizontally oriented refrigerator/freezer unit as a door or window.
